(19) United States
(12) Patent Application Publication
(10) Pub. No.: US 2009/0085130 A1
(43) Pub. Date: Apr. 2, 2009

(54) Semiconductor device

(76) Inventors: Kenji Suzuki, Albany, NY (US); Gishi Chung, Yamanashi-Ken (JP); Kazuya Okubo, Tokyo-To (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 10/585,828

(22) PCT Filed: Jan. 28, 2005
(86) PCT No.: PCT/JP05/01245

§ 371 Date: Aug. 29, 2008

(30) Foreign Application Priority Data
Jan. 29, 2004 (JP) 2004-021924

(51) Int. Cl. H01L 29/78

(52) U.S. Cl. 257/411; 257/E29.255

(57) ABSTRACT

The present invention relates to a semiconductor device comprising a semiconductor substrate (1), a gate insulator formed on this substrate, such as a gate oxide film (2), and a gate electrode (3) formed on the insulator. The gate electrode (3) has a metallic compound film (3a). This metallic compound film (3a) is formed by CVD using a material containing a metal carbonyl, e.g., W(CO)₆ gas, and at least one of a Si-containing gas and a N-containing gas. The work function of the metallic compound film (3a) thus formed is controllable by the Si and/or N content of the film.

### TECHNICAL FIELD

The present invention relates to a MOS device having a gate electrode that is formed on a gate insulator provided on a semiconductor substrate.

### BACKGROUND ART

Heretofore, polysilicon (poly-Si) has been used as a material for gate electrodes of MOS transistors. Conventional methods of controlling the threshold voltages of MOS transistors include the method called channel doping, in which the channel region is doped with an impurity, and the method in which the poly-Si film is doped with an impurity.

However, since semiconductor devices have come to be made finer than ever, the channel doping is disadvantageous in that an increase in impurity concentration in the channel region affects carriers. The poly-Si doping is also disadvantageous in that the passing of the impurity through the underlying gate oxide film produces a depletion layer at the interface between the poly-Si film and the underlying gate oxide film. The depletion film makes the gate electrode in operation poor in electrical characteristics and also makes it difficult to make the gate oxide film thinner. Furthermore, increases in the level of integration and the speed of LSIs have generated demand for gate electrodes having lower resistance. Since it is difficult to meet this demand with poly-Si, lower-resistance materials for gate electrodes have come to be sought after.

In order to meet this demand, research is being carrier out to use, as materials for gate electrodes, W (tungsten)-containing films, which produce no depletion layers and have lower resistance. The work function of W is unfavorably higher than the mid-gap of Si (silicon). However, WSiₓ, a compound of W and Si, can have a work function close to the mid-gap of silicon, so that it can control the threshold voltages of both p-type transistors and n-type transistors. For this reason, WSiₓ is suitable as a material for gate electrodes of CMOS devices. With respect to the structure of gate electrodes using WSiₓ, there have been proposed a single WSiₓ layer structure and a WSiₓ/poly-Si layered structure in which a poly-Si film is layered over a WSiₓ film (see Japanese Laid-Open Patent Publications No. 153804/1996 and No. 303412/1998, for example).

To form such a W-containing film, although physical vapor deposition (PVD) was used in the past, chemical vapor deposition (CVD) has come to be used in recent years. In the chemical vapor deposition it is not necessary to melt W, a high-melting-point metal, and the chemical vapor deposition can satisfactorily meet the demand for more minute devices.

Such a CVD-W-containing film is produced by using, as a starting material for film deposition, tungsten hexafluoride (WF₆) gas, for example. However, the mask pattern prescribed in the design rule has been getting finer in recent years, and if a gas containing F (fluorine) is used, such a problem occurs that F adversely affects the film quality of the underlying gate oxide film and degrades it.

On the other hand, the metal/silicon layered gate structure in which a film of silicon such as poly-Si or amorphous silicon is layered over a metal-containing electrically conductive layer such as a W-containing film, and the silicon/metal layered gate structure in which a metal-containing electrically conductive layer such as a W-containing film is layered over a silicon film are disadvantageous in that Si contained in the silicon film diffuses into the metal-containing electrically conductive layer in high-temperatures processes in the course of production so as to make silicide formation progress at the interface between the silicon film and the metal-containing electrically conductive layer.

### DISCLOSURE OF THE INVENTION

Under these circumstances, the present invention was accomplished. An object of the present invention is to provide a semiconductor device whose threshold voltage is controllable, while providing a gate electrode having reduced resistance and solving the problem of degradation of a gate insulator due to F. Another object of the present invention is to provide a semiconductor device having a gate electrode composed of a laminate of a metal-containing electrically conductive layer and a silicon film, in which Si contained in the silicon film can be effectively prevented from diffusing into the metal-containing electrically conductive layer.

In order to fulfil the above-described objects, the present invention provides a semiconductor device comprising a semiconductor substrate, a gate insulator formed on the substrate, and a gate electrode having a metallic compound film, the gate electrode being formed on the insulator, wherein: the metallic compound film in the gate electrode is formed by CVD using a material containing a metal carbonyl, and at least one of a Si-containing material, a N-containing material and C-containing material; and the metallic compound film contains the metal in the metal carbonyl and at least one of Si, N and C.

The resistance of the gate electrode having the metallic compound film according to the present invention can be made lower than that of conventional polysilicon gate electrodes. In addition, since a material containing a metal carbonyl is used to form the metallic compound film, degradation of the gate insulator due to diffusion of F never occurs unlike in the case where a F-containing gas is used as a material for film deposition.

Further, the work function of the metallic compound film can be varied by changing the content of at least one of Si and N in the film, and the barrier properties of the metallic compound film to the silicon film can be varied by changing the content of at least one of N and C in the film. Therefore, by changing the content of at least one of Si, N and C in the metallic compound film, it is possible to vary the work function and/or barrier properties to the silicon film of the metallic compound film in the gate electrode of the semiconductor device of the present invention. Thus, a gate electrode having the desired work function and/or barrier properties can be obtained, and a higher degree of freedom can be given to the designing of the whole semiconductor device.

In particular, by changing the content of at least one of Si and N in the metallic compound film, it is possible to change the work function of the film and thus to control the threshold voltage of the gate electrode. Moreover, by changing particularly the content of at least one of N and C in the metallic compound film, the barrier properties of the metallic compound film to the silicon film can be varied so that Si contained in the silicon film can be effectively prevented from diffusing into the metallic compound film.

In this case, fine adjustment may be made on the threshold voltage of the gate electrode by doping the metallic compound film with an n-type impurity or p-type impurity.

The gate electrode may further comprise a silicon film formed on the metallic compound film. Si contained in this silicon film can be effectively prevented from diffusing into the metallic compound film.

Preferably, in this case, the gate electrode further has a barrier layer formed between the metallic compound film and the silicon film, the barrier layer is formed by CVD using a material containing a metal carbonyl and at least one of a N-containing material and a C-containing material, and the barrier layer is a film of a metallic compound containing the metal in the metal carbonyl and at least one of N and C.

In this case, the barrier properties of the barrier layer to the silicon film can be varied by changing the content of at least one of N and C in the barrier layer. The barrier properties of the barrier layer to the silicon film can thus be changed independently from the work function of the metallic compound film and/or barrier properties of the metallic compound film. Therefore, a higher degree of freedom can be given to the designing of the gate electrode and also to the designing of the whole semiconductor device.

Further, the present invention also provides a semiconductor device comprising a semiconductor substrate, a gate insulator formed on the substrate, and a gate electrode formed on the insulator, wherein: the gate electrode comprises: a metal-containing electrically conductive layer; a barrier layer formed on the electrically conductive layer; and a silicon film formed on the barrier layer; the barrier layer is formed by the use of a material containing a metal carbonyl, and at least one of a N-containing material and a C-containing material; and the barrier layer is a film of a metallic compound containing the metal in the metal carbonyl and at least one of N and C.

Also in this case, by changing the content of at least one of N and C in the barrier layer, it is possible to vary the barrier properties of the barrier layer to the silicon film. Si contained in the silicon film can thus be effectively prevented from diffusing into the electrically conductive layer so that silicide formation is prevented from occurring at the interface between the electrically conductive layer and the silicon film. Not only CVD but also such a conventionally known method as physical deposition can be employed as a method of forming the metal-containing electrically conductive layer.

The metal constituting the metal carbonyl is selected from the group consisting of W, Ni, Co, Ru, Mo, Re, Ta, and Ti.

For example, the metal carbonyl is W(CO)₆.

Especially when a W silicide film formed by the use of a W(CO)₆-containing material and a Si-containing material is used as the metallic compound film in the gate electrode, its work function can be made close to the mid-gap of silicon. Therefore, such a film makes it possible to control the threshold voltages of CMOS devices, either pMOS transistors or nMOS transistors, for example.

The Si-containing material is selected from the group consisting of silane, disilane, and dichlorosilane.

The N-containing material is selected from the group consisting of ammonia and monomethyl hydrazine.

The C-containing material is selected from the group consisting of ethylene, allyl alcohol, formic acid, and tetrahydrofuran.

### BRIEF DESCRIPTION OF THE DRAWINGS

FIG. 1 is a sectional view for explaining a production process of a semiconductor device according to the first embodiment of the present invention.

FIG. 2 is a graph showing a change in work function due to a change in the ratio of Si or N to W in the W compound film.

FIG. 3 is a sectional view for explaining a production process of a semiconductor device according to the second embodiment of the present invention.

FIG. 4 is a sectional view for explaining a production process of a semiconductor device according to the third embodiment of the present invention.

FIG. 5 is a sectional view for explaining a production process of a semiconductor device according to the fourth embodiment of the present invention.

FIG. 6 is a sectional view for explaining a production process of a semiconductor device according to the fifth embodiment of the present invention.

FIG. 7 is a sectional view showing one example of a CVD system useful for deposition of a W compound film of the present invention.

### BEST MODE FOR CARRYING OUT THE INVENTION

With reference to the accompanying drawings, an embodiment of the present invention will be specifically described hereinafter.

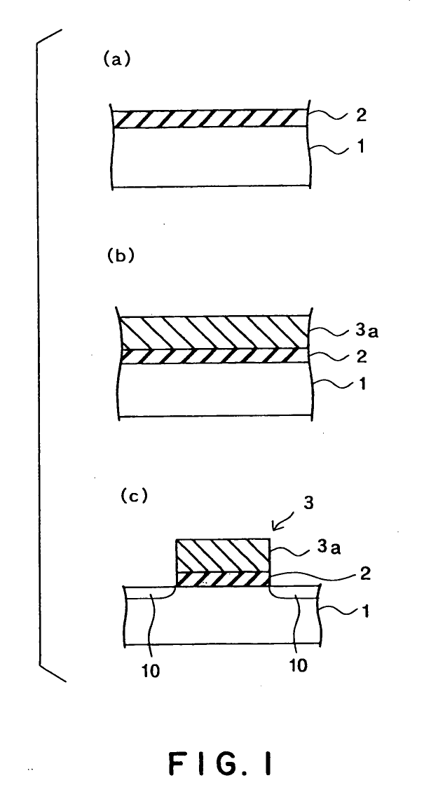

FIG. 1 is a sectional view for explaining a production process of a semiconductor device according to the first embodiment of the present invention.

As shown in FIG. 1(a), a gate oxide film 2 serving as a gate insulator is first formed on a Si substrate 1, a semiconductor substrate. Subsequently, a W compound film 3a containing W and at least one of Si and N is formed on the gate oxide film 2 by CVD using W(CO)₆ gas, a W carbonyl gas, and at least one of a Si-containing gas and a N-containing gas, as shown in FIG. 1(b). The thickness of the gate oxide film 2 and that of the W compound film 3a are 0.8 to 5 nm and 10 to 200 nm, respectively, for example. Resist application, patterning, etching, etc. are then conducted after carrying out thermal treatment, and ion implantation or the like is further conducted so as to make an impurity-diffused region 10. Thus, there is obtained a MOS device (a semiconductor device including a MOS structure) having a gate electrode 3 consisting of the W compound film 3a containing W and at least one of Si and N, as shown in FIG. 1(c).

The Si or N content (contained amount) of the W compound film 3a constituting the gate electrode 3 can be freely changed by controlling the film deposition conditions such as the flow rate of W(CO)₆ gas, the flow rate of the Si-containing gas, the flow rate of the N-containing gas, the substrate temperature, and the pressure in the processing chamber. By changing these conditions, there can be formed a WSiₓ film with any composition, a WNₓ film with any composition, and a compound film with a composition that is a combination of the above two.

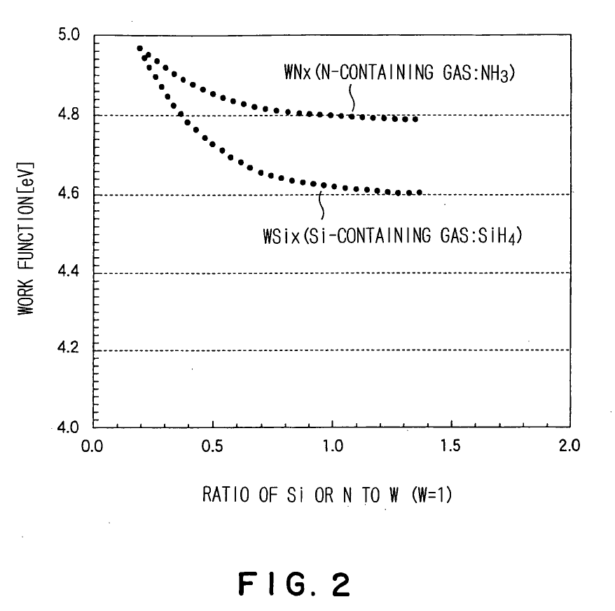

By changing the Si or N content of the W compound film, it is possible to change the work function of the film, as shown in FIG. 2. Therefore, by freely changing the Si or N content of the W compound film 3a, the desired work function can be obtained, and the threshold voltage of the gate electrode can be regulated to the desired value. Especially when the WSiₓ film is formed by the use of a Si-containing gas, the work function of the film can be made close to 4.6 eV, the mid-gap of silicon, if the ratio of W to Si is made 1:1.3. Such a film, therefore, makes it possible to control the threshold voltage of a CMOS device, either pMOS or nMOC, for example.

Further, since the gate electrode 3 is composed of the W compound film 3a, it can have lower resistance as compared with conventional polysilicon gate electrodes. Furthermore, W(CO)₆ gas, an organometallic gas, is used to deposit the W compound film 3a, and this gas does not contain F unlike WF₆ that has been used conventionally, so that degradation of the underlying gate oxide film due to the diffusion of F never occurs.

Silane, disilane, dichlorosilane, or the like can be used as the Si-containing gas, and ammonia, monomethyl hydrazine, or the like can be used as the N-containing gas. If necessary, the W compound film 3a may be doped with such an impurity ion as P, As, B or the like by ion implantation. Fine adjustment can thus be made on the threshold voltage of the gate electrode.

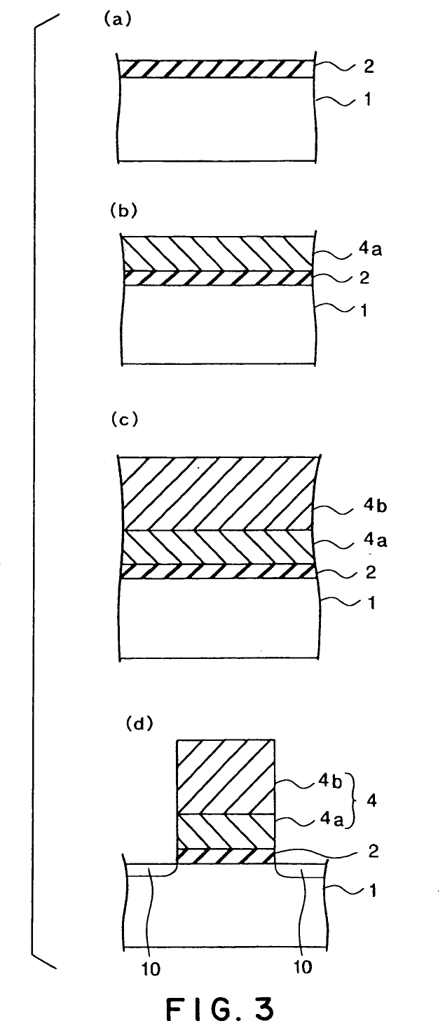

FIG. 3 is a sectional view for explaining a production process of a semiconductor device according to the second embodiment of the present invention.

In the second embodiment, a gate oxide film 2 is first formed on a Si substrate 1. Thereafter, a W compound film 4a containing W and at least one of Si and N is deposited on the gate oxide film 2 by CVD using W(CO)₆ gas and at least one of a Si-containing gas and a N-containing gas, as shown in FIG. 3(b). As shown in FIG. 3(c), a polysilicon (poly-Si) film 4b is further formed on the W compound film 4a by a proper method. The thickness of the W compound film 4a and the thickness of the poly-Si film 4b are 2 to 100 nm and 50 to 200 nm, respectively, for example. Resist application, patterning, etching, etc. are then conducted after carrying out thermal treatment, and ion implantation or the like is further conducted so as to form an impurity-diffused layer 10. Thus, there is obtained a MOS device having a two-layered gate electrode 4 consisting of the W compound film 4a and the poly-Si film 4b, as shown in FIG. 3(d).

As in the above-described first embodiment, by freely changing the Si or N content of the W compound film 4a constituting the gate electrode 4, the desired work function can be obtained, and the threshold voltage of the gate electrode can thus be regulated to the desired value. Especially when a N-containing gas is used to form the W compound film containing N, the film acquires the barrier properties to the poly-Si film 4b present on it. Such a W compound film effectively prevents Si contained in the poly-Si film 4b from diffusing into the W compound film 4a, so that silicide formation is prevented from occurring at the interface between the W compound film 4a and the poly-Si film 4b. Further, since the gate electrode 4 is composed of the W compound film 4a, it can have lower resistance as compared with conventional polysilicon gate electrodes. Furthermore, W(CO)₆ gas is used to deposit the W compound film 4a, so that degradation of the underlying gate oxide film due to the diffusion of F never occurs. The same gases as in the aforementioned first embodiment can be used as the Si-containing gas and the N-containing gas. If necessary, the laminate of the W compound film 4a and the poly-Si film 4b may be doped with such an impurity ion as P, As, B or the like by ion implantation.

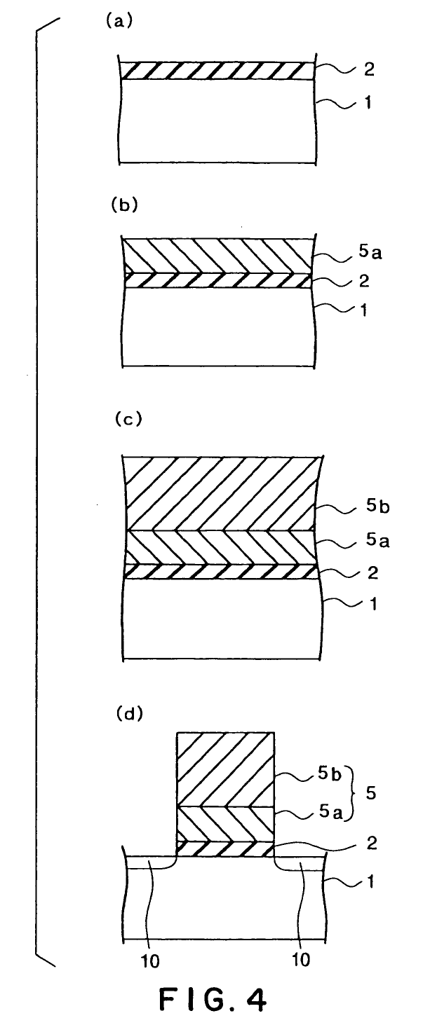

FIG. 4 is a sectional view for explaining a production process of a semiconductor device according to the third embodiment of the present invention.

In the third embodiment, a gate oxide film 2 is first formed on a Si substrate 1. Thereafter, a W compound film 5a containing W and at least one of Si, N and C is formed on the gate oxide film 2 by CVD using W(CO)₆ gas and at least one of a Si-containing gas, a N-containing gas, and a C-containing gas, as shown in FIG. 4(b). As shown in FIG. 4(c), a poly-Si film 5b is further formed on the W compound film 5a by a proper method. The thickness of the W compound film 5a and the thickness of the poly-Si film 5b are 2 to 100 nm and 50 to 200 nm, respectively, for example. Resist application, patterning, etching, etc. are then conducted after carrying out thermal treatment, and ion implantation or the like is further conducted to form an impurity-diffused layer 10. Thus, there is obtained a MOS device having a two-layered gate electrode 5 consisting of the W compound film 5a and the poly-Si film 5b, as shown in FIG. 4(d).

By controlling, in the deposition of the W compound film 5a, the film deposition conditions such as the flow rate of W(CO)₆ gas, the flow rate of the Si-containing gas, the flow rate of the N-containing gas, the flow rate of the C-containing gas, the substrate temperature, and the pressure in the processing chamber, it is possible to change freely the contents of Si, N and C in the W compound film 5a constituting the gate electrode 5. Thus, there can be obtained a WSiₓ film with any composition, a WNₓ film with any composition, a WCₓ film with any composition, and a compound film with a composition that is a combination of these compositions. As mentioned above, by changing the Si or N content of the W compound film, it is possible to change the work function of the film. Moreover, by changing the N or C content of the W compound film, it is possible to vary even the barrier properties of the W compound film to the poly-Si film. Therefore, by freely changing the contents of Si, N and C in the W compound film 5a, it is possible to obtain the desired work function and the desired barrier properties, and there can be obtained a gate electrode having the desired threshold voltage and the desired barrier properties.

Also in this embodiment, the gate electrode 5 is composed of the W compound film 5a, so that it can have lower resistance as compared with conventional polysilicon gate electrodes. Furthermore, since a gas containing a W carbonyl is used to form the W compound film, degradation of the underlying gate insulator due to diffusion of F never occurs.

The same gases as in the aforementioned first embodiment can be used as the Si-containing gas and the N-containing gas, and allyl alcohol, ethylene, formic acid, tetrahydrofuran, or the like can be used as the C-containing gas. If necessary, the laminate of the W compound film 5a and the poly-Si film 5b may be doped with such an impurity ion as P, As, B or the like by ion implantation.

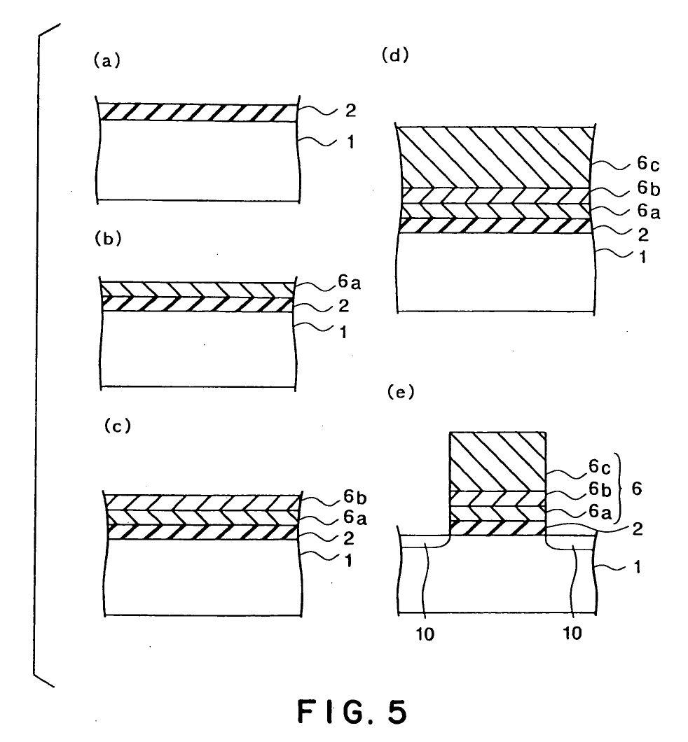

FIG. 5 is a sectional view for explaining a production process of a semiconductor device according to the fourth embodiment of the present invention.

In the fourth embodiment, a gate oxide film 2 is first formed on a Si substrate 1. Thereafter, a first W compound film 6a containing W and at least one of Si and N is formed on the gate oxide film 2 by CVD using W(CO)₆ gas and at least one of a Si-containing gas and a N-containing gas, as shown in FIG. 5(b). As shown in FIG. 5(c), a W compound film 6b containing W and at least one of N and C, is formed on the W compound film 6a by CVD using W(CO)₆ gas and at least one of a N-containing gas and a C-containing gas. The W compound film 6b has a composition different from a composition of the W compound film 6a. A poly-Si film 6c is then further formed on the W compound film 6b by a proper method, as shown in FIG. 5(d). The thickness of the W compound film 6a, the thickness of the W compound film 6b, and the thickness of the poly-Si film 6c are 2 to 100 nm, 2 to 100 nm, and 50 to 200 nm, respectively, for example. Resist application, patterning, etching, etc. are then conducted after carrying out thermal treatment, and ion implantation or the like is further conducted so as to form an impurity-diffused layer 10. Thus, there is obtained a MOS device having a three-layered gate electrode 6 consisting of the W compound film 6a, the W compound film 6b, and the poly-Si film 6c, as shown in FIG. 5(e).

As in the above-described first embodiment, by freely changing the Si or N content of the W compound film 6a that is in contact with the gate oxide film 2 in the gate electrode 6, it is possible to obtain the desired work function and thus to regulate the threshold voltage of the gate electrode to the desired value. Further, the W compound film 6b containing W and at least one of N and C is provided between the W compound film 6a and the poly-Si film 6c. This W compound film 6b serves as a barrier layer that prevents the W compound film 6a and the poly-Si film 6c from interacting with each other, so that Si contained in the poly-Si film 6c can be effectively prevented from diffusing into the W compound film 6a. In particular, a W compound film containing C, formed by the use of a C-containing gas, is excellent in the barrier properties to the poly-Si film, so that it is suitable as a barrier layer. According to this embodiment, since the work function and the barrier properties can be separately controlled depending on needs, a higher degree of freedom can be given to the designing of the device. The same gases as in the aforementioned first embodiment can be used as the Si-containing gas and the N-containing gas, and the same gas as in the above-described third embodiment can be used as the C-containing gas. If necessary, the laminate of the W compound film 6a, the W compound film 6b, and the poly-Si film 6c may be doped with such an impurity ion as P, As, B or the like by ion implantation.

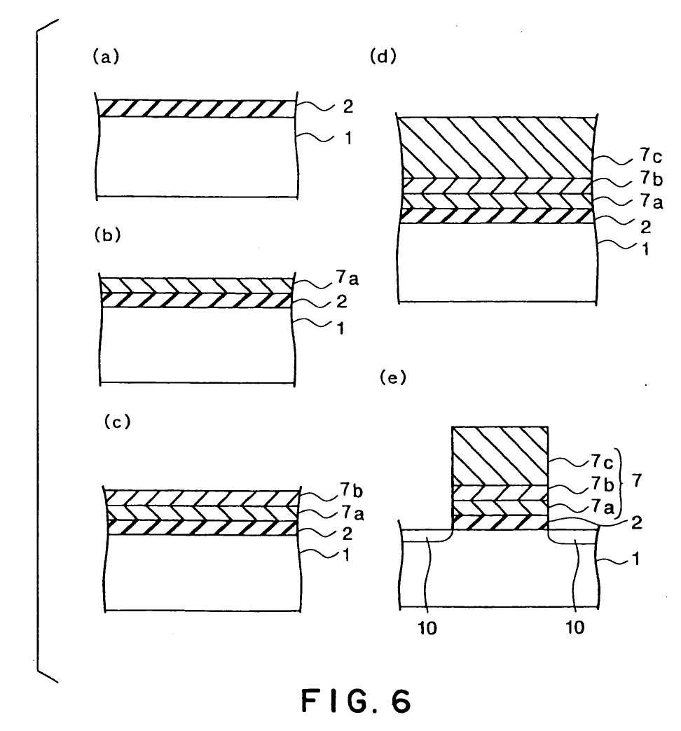

FIG. 6 is a sectional view for explaining a production process of a semiconductor device according to the fifth embodiment of the present invention.

In a semiconductor device having a gate electrode composed of a laminate of a metal-containing electrically conductive layer and a poly-Si film, the fifth embodiment is to prevent diffusion of Si contained in the poly-Si film into the electrically conductive layer. In the fifth embodiment, a gate oxide film 2 is first formed on a Si substrate 1, a semiconductor substrate, as shown in FIG. 6(a). Subsequently, a W-containing film 7a serving as the metal-containing electrically conductive layer is formed on the gate oxide film 2. To form this W-containing film 7a, not only CVD but also such a conventionally known method as PVD may be used. A barrier layer 7b composed of a compound containing W and at least one of N and C is then formed on the W-containing film 7a using W(CO)₆ gas and at least one of a N-containing gas and a C-containing gas, as shown in FIG. 6(c). As shown in FIG. 6(d), a poly-Si film 7c is further formed on the barrier layer 7b by a proper method. The thickness of the W-containing film 7a, the thickness of the barrier layer 7b, and the thickness of the poly-Si film 7c are 2 to 100 nm, 2 to 100 nm, and 50 to 200 nm, respectively, for example. Resist application, patterning, etching, etc. are then conducted after carrying out thermal treatment, and ion implantation or the like is further conducted so as to form an impurity-diffused layer 10. Thus, there is obtained a MOS device having a three-layered gate electrode 7 consisting of the W-containing film 7a, the barrier layer 7b, and the poly-Si film 7c, as shown in FIG. 6(e).

In the electrode gate 5, since the barrier layer 7b composed of a W compound containing W and at least one of N and C is provided between the W-containing film 7a and the poly-Si film 7c in the above-described manner, Si contained in the poly-Si film 7c can be effectively prevented from diffusing into the W-containing film 7a. In particular, a W compound film containing C, formed by using a C-containing gas, is excellent in the barrier properties to the poly-Si film, so that it is suitable as a barrier layer. The same gas as in the aforementioned first embodiment can be used as the N-containing gas, and the same gas as in the above-described third embodiment can be used as the C-containing gas. The metal-containing electrically conductive layer is not limited to the W-containing film 7a, and when a film of a single metal or of a metallic compound that readily reacts with the poly-Si film is used as the electrically conductive layer, the same effects can be obtained. Although this embodiment has been described with reference to the case where the poly-Si film 7c is layered over the W-containing film 7a, the same effects can also be obtained even when the metal-containing electrically conductive layer is layered over the poly-Si film.

Next, a method of forming the above-described W compound film by CVD using W(CO)₆ gas and at least one of a Si-containing gas, a N-containing gas, and a C-containing gas, and a deposition system suitable for the method will be described.

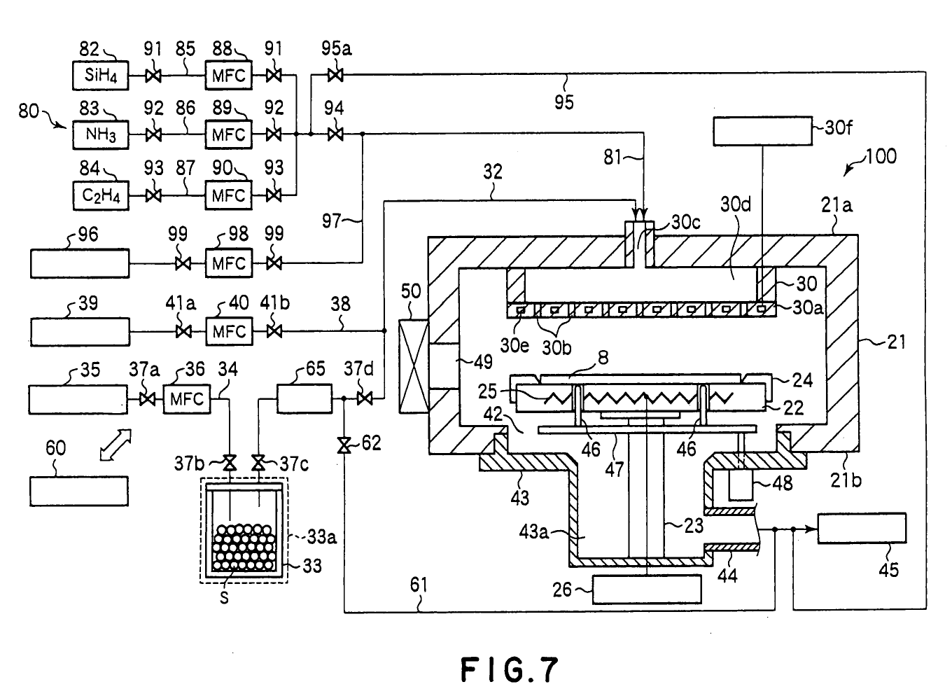

FIG. 7 is a sectional view diagrammatically showing one example of a CVD system for forming a W compound film.

This deposition system 100 has an airtight, nearly cylindrical processing vessel (processing container) 21. The bottom wall 21b of the processing vessel 21 has a round opening 42 in its center. An exhaust vessel (exhaust container) 43 is connected to the bottom wall 21b of the processing vessel 21 so that the two vessels internally communicate each other through the opening 42. In the processing vessel 21, a susceptor 22, made of ceramic such as AIN, for horizontally holding a wafer, a semiconductor substrate, is provided. This susceptor 22 is supported by a cylindrical supporting member 23 extending upward from the center of the bottom of the exhaust vessel 43. A guide ring 24 for guiding a wafer 8 is provided on the outer edge of the susceptor 22. Further, an electrical resistance heater 25 is embedded in the susceptor 22. This heater 25 heats the susceptor 22 with electric power supplied by a power source 26, and the wafer 8 is heated with the heat of the susceptor 22. Due to this heat, the W(CO)₆ gas introduced into the processing vessel 21 thermally decomposes, as will be described later. A controller (not shown in the figure) is connected to the power source 26 for the heater, and by this controller, the output of the heater 25 is controlled according to the signal sent by a temperature sensor not shown in the figure. Further, a heater (not shown in the figure) is embedded also in the wall of the processing vessel 21, and with it, the wall of the processing vessel 21 is heated to a temperature of about 40 to 80° C.

In the susceptor 22, three wafer-supporting pins 46 (only two of them being shown in the figure) for supporting and elevating the wafer 8 are provided so that they can go up and project above the surface of the susceptor 22 and go down to the original position inside the susceptor 22. These wafer-supporting pins 46 are fixed to a support plate 47. A drive mechanism 48 such as an air cylinder allows the wafer-supporting pins 46 to go up and down with the support plate 47.

A shower head 30 is attached to the ceiling wall 21a of the processing vessel 21. The bottom of this shower head 30 is a shower plate 30a having a large number of gas jets 30b through which a gas is jetted toward the susceptor 22. The shower head 30 has, in its upper wall, a gas inlet port 30c through which a gas is introduced into the shower head 30. To this gas inlet port 30c is connected one end of a pipe 32 for supplying W(CO)₆ gas as a W carbonyl gas. One end of a pipe 81 for supplying silane (SiH₄) gas as a Si-containing gas, ammonia (NH₃) gas as a N-containing gas, and ethylene (C₂H₄) gas as a C-containing gas, is also connected to the gas inlet port 30c. The internal space of the shower head 30 is formed as a diffusion chamber 30d. The shower plate 30a has concentric cooling-medium-flow channels 30e to which a cooling medium such as cooling water is fed from a cooling medium supply source 30f. With this cooling medium, the internal temperature of the shower head 30 can be regulated to 20 to 100° C. so that the W(CO)₆ gas is prevented from decomposing in the shower head 30.

The other end of the pipe 32 is inserted into a W source material container 33 in which solid W(CO)₆ source material S, metal carbonyl ray material, is contained. A heater 33a is provided around the W source material container 33. A carrier gas pipe 34 is inserted into the W source material container 33. Through this pipe 34, a carrier gas, e.g., Ar gas, is blown into the W source material container 33 from the carrier gas supply source 35. On the other hand, the solid W(CO)₆ source material S placed in the W source material container 33 is heated with the heater 33a and sublimes to be W(CO)₆ gas. Along with the carrier gas, this W(CO)₆ gas is supplied to the diffusion chamber 30d through the pipe 32. The pipe 34 has a mass flow controller 36 and valves 37a, 37b provided before and after the mass flow controller 36. The pipe 32 has a flow meter 65 with which the flow rate of the W(CO)₆ gas is determined, for example, on the basis of the amount of the gas, as well as valves 37c, 37d provided before and after the flow meter 65. Further, a pre-flow line 61 is connected to the pipe 32 on the downstream side of the flow meter 65. This pre-flow line 61 is connected to an exhaust pipe 44 that will be described later. Further, the pre-flow line 61 has a valve 62 right before it meets the pipe 32. Heaters (not shown in the figure) are provided around the pipes 32, 34, 61, and with these heaters, the pipes are heated to temperatures at which W(CO)₆ gas does not solidify, e.g., 20 to 100° C., preferably 25 to 60° C.

A purge gas supply source 39 is connected to the pipe 32 at the middle of the pipe 32 via a purge gas pipe 38. The purge gas supply source 39 supplies, as a purge gas, an inert gas such as Ar gas, He gas or N₂ gas, or H₂ gas. With this purge gas, the gas, which was used for film deposition and is remaining in the pipe 32, is purged and the processing vessel 21 is exhausted. The purge gas pipe 38 has a mass flow controller 40 and valves 41a, 41b provided before and after the mass flow controller 40.

On the other hand, the other end of the pipe 81 is connected to a gas supply system 80. The gas supply system 80 has a SiH₄ gas supply source 82 that supplies SiH₄ gas, a NH₃ gas supply source 83 that supplies NH₃ gas, and a C₂H₄ gas supply source 84 that supplies C₂H₄ gas. To the gas supply sources 82, 83, 84, gas lines 85, 86, 87 are connected, respectively. The gas line 85 has a mass flow controller 88 and valves 91 provided before and after the mass flow controller 88, the gas line 86 has a mass flow controller 89 and valves 92 provided before and after the mass flow controller 89, and the gas line 87 has a mass flow controller 90 and valves 93 provided before and after the mass flow controller 90. Each gas line is connected to the diffusion chamber 30d through the pipe 81. To the pipe 81, a pre-flow line 95 is connected, and this pre-flow line 95 is connected to an exhaust pipe 44 that will be described later. The pre-flow line 95 has a valve 95a right before it meets the pipe 81.

A purge gas supply source 96 is connected to the pipe 81 at the middle of the pipe 81 by means of a purge gas pipe 97. The purge gas supply source 96 supplies, as a purge gas, an inert gas such as Ar gas, He gas or N₂ gas, or H₂ gas. With this purge gas, the gas, which was used for film deposition and is remaining in the pipe 81, is purged and the processing vessel 21 is exhausted. The purge gas pipe 97 has a mass flow controller 98 and valves 99 provided before and after the mass flow controller 98.

The mass flow controllers, the valves, and the flow meter 65 are under control of a controller 60. The controller 60 controls the start or suspension of the supply of the carrier gas, W(CO)₆ gas, SiH₄ gas, NH₃ gas, C₂H₄ gas, and the purge gas, and regulates the flow rates of these gases to predetermined ones. The flow rate of W(CO)₆ gas to be supplied to the gas diffusion chamber 30d in the processing vessel 21 is regulated by controlling the flow rate of the carrier gas by the mass flow controller 36 according to the amount of the gas determined by the flow meter 65.

An exhaust system 45 including a high-speed vacuum pump is connected to the side of the above-described exhaust vessel 43 by means of an exhaust pipe 44. By operating this exhaust system 45, the gas in the processing vessel 21 is uniformly discharged into the space 43a in the exhaust vessel 43 and is then exhausted to the outside through the exhaust pipe 44. The pressure in the processing vessel 21 can thus be reduced to the desired degree of vacuum at a high speed.

The processing vessel 21 has, in its sidewall, an opening 49 through which a wafer 8 is carried between the processing vessel 21 and a carrier chamber (not shown in the figure) present next to the deposition system 100, and a gate valve 50 for opening or closing this opening 49.

Deposition of a W compound film by the use of the above-described deposition system is conducted in the following manner. First, a wafer 8 having a gate oxide film formed beforehand on its surface is carried in the processing vessel 21 through the opening 49 opened by opening the gate valve 50 and is placed on the susceptor 22. Subsequently, the susceptor 22 is heated with the heater 25, thereby heating the wafer 8 with the heat of the susceptor 22. The processing vessel 21 is exhausted by the vacuum pump in the exhaust system 45 so that it is vacuumed to a pressure of 6.7 Pa or less. In this step, it is desirable that the temperature to which the wafer 8 is heated be from 100 to 600° C.

Subsequently, the valves 37a, 37b are opened and a carrier gas, e.g., Ar gas, is blown into the W source material container 33 containing solid W(CO)₆ source material S from the carrier gas supply source 35. The W(CO)₆ source material S is heated with the heater 33a so that it generates W(CO)₆ gas. The valve 37c and the valve 62 are then opened in order to conduct pre-flowing of W(CO)₆ gas, which the gas is allowed to flow in the pre-flow line 61 and is exhausted. By conducting this pre-flowing for a predetermined period of time, the flow rate of W(CO)₆ gas is stabilized. Subsequently, the valve 62 is closed, and, at the same time, the valve 37d is opened, thereby introducing the W(CO)₆ gas into the pipe 32 and feeding it to the gas diffusion chamber 30d through the gas inlet port 30c. At this time, it is desirable that the pressure in the processing vessel 21 be from 0.01 to 500 Pa. Not only Ar gas but also other gas may be used as the carrier gas. For example, N₂ gas, H₂ gas, He gas, or the like can be used as the carrier gas.

On the other hand, simultaneously with the supply of W(CO)₆ gas to the gas diffusion chamber 30d, at least one of SiH₄ gas, NH₃ gas, and C₂H₄ gas is supplied to the gas diffusion chamber 30d. A gas to be supplied is first pre-flowed in the pre-flow line 95 and exhausted. By conducting the pre-flowing of the gas for a predetermined period of time, the flow rate of the gas is stabilized. Thereafter, the gas is supplied to the gas diffusion chamber 30d through the pipe 81 simultaneously with the supply of W(CO)₆ gas to the gas diffusion chamber 30d.

During the supply of W(CO)₆ gas and at least one of SiH₄ gas, NH₃ gas, and C₂H₄ gas to the gas diffusion chamber 30d, they are maintained at predetermined flow rates. For example, the flow rate of W(CO)₆ gas is regulated to 0.0001 to 0.5 L/min, the flow rate of SiH₄ gas, to 0.001 to 1 L/min, the flow rate of NH₃ gas, to 0.001 to 1 L/min, and the flow rate of C₂H₄ gas, to 0.001 to 1 L/min.

W(CO)₆ gas and at least one of SiH₄ gas, NH₃ gas, and C₂H₄ gas that have been supplied to the gas diffusion chamber 30d diffuse in the gas diffusion chamber 30d and are uniformly supplied, through the gas jets 30b in the shower plate 30a, to the surface of the wafer 8 in the processing vessel 21. On the heated wafer 8 surface, W produced by thermal decomposition of W(CO)₆ reacts with Si, N or C in SiH₄ gas, NH₃ gas, or C₂H₄ gas so as to form a film of the desired W compound. In the case where SiH₄ gas, NH₃ gas, and C₂H₄ gas are used singly, WSiₓ, WNₓ, and WCₓ are formed, respectively. Two or more of the gases produce a compound whose composition is a combination of these compositions. By controlling the film deposition conditions such as the species and/or the gas flow rates of the gases to be introduced into the processing vessel 21, the substrate temperature, and the pressure in the processing vessel, it is possible to change freely the composition of the W compound film and thus to control the characteristics of the film. Namely, by using W(CO)₆ gas and at least one of SiH₄ gas, NH₃ gas, and C₂H₄ gas and by controlling the flow rates of these gasses and the other film deposition conditions, it is possible to control the work function of the W compound film and thus to control the threshold voltage of the gate electrode, and, moreover, to obtain the desired barrier properties.

As soon as the W compound film has reached the desired thickness, the supply of the gases is suspended. Thereafter, a purge gas is introduced into the processing vessel 21 from the purge gas supply sources 39, 96 so as to purge the gasses which were used for film deposition and are remaining in the processing vessel 21. Then, the gate valve 50 is opened, and the wafer 8 is carried out of the processing vessel 21 through the opening 49.

A layered structure composed of W compound films as shown in FIG. 5 can be obtained in the following manner by using the system shown in FIG. 7. First, W(CO)₆ gas and at least one of SiH₄ gas and NH₃ gas are supplied at flow rates that are in a predetermined ratio so as to form a first W compound film 6a. As soon as the W compound film 6a has reached a predetermined thickness, the supply of the gasses is suspended and the processing vessel 21 is purged. Thereafter, W(CO)₆ gas and at least one of SiH₄ gas and NH₃ gas are supplied at flow rates that are in a predetermined ratio so as to form a second W compound film (barrier layer) 6b. Thus, by using different film deposition conditions, such as the gas species of the gasses to be introduced into the processing vessel, the flow rates of the gasses, the substrate temperature, and the pressure in the processing vessel, for the deposition of the first W compound film and the deposition of the second W compound film, the two W compound films having different compositions can be continuously deposited in one processing vessel. A layered structure composed of the W compound films can thus be obtained at extremely high efficiency without facing troubles such as oxidation.

The aforementioned embodiment has been described with reference to the case where W compound films containing W are formed, as the metallic compound film and the barrier layer for the gate electrode, by using W(CO)₆ as the metal carbonyl. The present invention is not limited to this. For example, the present invention is effective for the case where a metallic compound film containing at least one of W, Ni, Co, Ru, Mo, Re, Ta, and Ti is formed by using, as the metal carbonyl, at least one compound selected from W(CO)₆, Ni(CO)₄, Co₂(CO)₈, Ru₃(CO)₁₂, Mo(CO)₆, Re₂(CO)₁₀, Ta(CO)₆, and Ti(CO)₆. The material to be used for forming a metallic compound film by CVD is not limited to a gas, and a liquid or solid material may also be used. Further, although a poly-Si film is used for the layered structure of the gate electrode in the above embodiment, not limited to the poly-Si, a film of silicon such as amorphous silicon may also be used.

Furthermore, in the above-described embodiment, a laminate of two W compound films whose compositions are different from each other is formed in one processing chamber. The present invention is not limited to this. That is to say, the number of the films to be formed in one processing vessel is not limited to two, and it may be three or more. Moreover, it is purposive that at least one of a plurality of the layered films is a metallic film containing the metal in the metal carbonyl. By using such a metallic film for the gate electrode, it is possible to achieve reduction in the resistance of the gate electrode.

Furthermore, although a Si substrate is used as the semiconductor substrate in the aforementioned embodiment, not limited to the Si substrate, the present invention is also applicable to other substrate such as an SOI substrate.

1. A semiconductor device comprising:
a semiconductor substrate;
a gate insulator formed on the substrate; and
a gate electrode having a metallic compound film, the gate electrode being formed on the insulator,
wherein: the metallic compound film in the gate electrode is formed by CVD using a material containing a metal carbonyl, and at least one of a Si-containing material and a N-containing material;
the metallic compound film contains the metal in the metal carbonyl and at least one of Si and N; and
the work function of the metallic compound film can be controlled by changing the content of at least one of Si and N in the metallic compound film.

2. The semiconductor device according to claim 1, wherein the metal constituting the metal carbonyl is selected from the group consisting of W, Ni, Co, Ru, Mo, Re, Ta, and Ti.

3. The semiconductor device according to claim 1, wherein the metal carbonyl is W(CO)₆.

4. The semiconductor device according to claim 1, wherein the Si-containing material is selected from the group consisting of silane, disilane, and dichlorosilane.

5. The semiconductor device according to claim 1, wherein the N-containing material is selected from the group consisting of ammonia and monomethyl hydrazine.

6. The semiconductor device according to claim 1, wherein the metallic compound film is formed by using further a C-containing material, and the metallic compound film contains the metal in the metal carbonyl, at least one of Si and N, and C.

7. The semiconductor device according to claim 1, wherein the metallic compound film is doped with an n-type impurity or a p-type impurity.

8. The semiconductor device according to claim 1, wherein the gate electrode further comprises a silicon film formed on the metallic compound film.

9. The semiconductor device according to claim 6, wherein the C-containing material is selected from the group consisting of ethylene, allyl alcohol, formic acid, and tetrahydrofuran.

10. A semiconductor device comprising:
a semiconductor substrate;
a gate insulator formed on the substrate; and
a gate electrode formed on the insulator,
wherein: the gate electrode comprises: a metallic compound film; a barrier layer formed on the metallic compound film; and a silicon film formed on the barrier layer;
the barrier layer is formed by the use of a material containing a metal carbonyl, a N-containing material, and a C-containing material;
the barrier layer contains the metal in the metal carbonyl, N, and C;
the metallic compound film is formed by the use of a material containing a metal carbonyl, and at least one of a Si-containing material and a N-containing material;
the metallic compound film contains the metal in the metal carbonyl and at least one of Si and N; and
the work function of the metallic compound film can be controlled by changing the content of at least one of Si and N in the metallic compound film.

11. The semiconductor device according to claim 10, wherein the metal constituting the metal carbonyl is selected from the group consisting of W, Ni, Co, Ru, Mo, Re, Ta, and Ti.

12. The semiconductor device according to claim 10, wherein the metal carbonyl is W(CO)₆.

13. The semiconductor device according to claim 10, wherein the N-containing material is selected from the group consisting of ammonia and monomethyl hydrazine.

14. The semiconductor device according to claim 10, wherein the C-containing material is selected from the group consisting of ethylene, allyl alcohol, formic acid, and tetrahydrofuran.
